(19) United States
(12) Patent Application Publication
(10) Pub. No.: US 2020/0196479 A1
(43) Pub. Date: Jun. 18, 2020

(54) FRAME, ELECTRONIC DEVICE AND METHOD FOR MANUFACTURING THE FRAME

(71) Applicant: FIH Precision Electronics (Lang Fang) Co., Ltd., Langfang (CN)

(72) Inventors: HENG ZHANG, Langfang (CN); YU-TSAI WANG, New Taipei (TW); YING-BO YANG, Langfang (CN); SHUI-YING CHEN, Shenzhen (CN)

(21) Appl. No.: 16/361,501

(22) Filed: Mar. 22, 2019

(30) Foreign Application Priority Data
Dec. 15, 2018 (CN) 201811537766.8

(51) Int. Cl. H05K 7/18; B29C 45/14

(52) U.S. Cl. CPC H05K 7/18; B29K 2705/00; B29C 45/14336

(57) ABSTRACT

A frame includes a metal plate, an adhesive film and a plastic border. The plastic border is wrapped around a periphery of the metal plate, the adhesive film is sandwiched between the plastic border and the metal plate. The disclosure also provides an electronic device having the frame and a method for manufacturing the frame.

### FIELD

The subject matter herein generally relates to a frame, an electronic device having the frame and a method for manufacturing the frame.

### BACKGROUND

At present, there are two main processing method for a frame which is waterproof. One method is to directly form a middle structure by die casting aluminum, and then to perform a nano-injection on the middle structure to obtain a composite frame of aluminum and plastic. The other method is to directly form a middle structure by die casting aluminum, then to perform a conventional injection on the middle structure to obtain a composite frame of aluminum and plastic, and apply a sealant on the inner surface of the composite frame for waterproofing.

However, in the first method, an ash layer will be produced on the surface of the middle structure during the nano-injection treatment process, and a bonding strength between aluminum and plastic of the nano-injection treatment process is about 70% of a bonding strength between aluminum and plastic of the conventional injection treatment process. In the second method, the sealant applied on the inner surface of the composite frame occupies a limited space inside the mobile phone, and affects the design of the electronic device. Because the composite frame needs to be connected with the electronic elements received in the composite frame, the sealant can't be applied on the whole inner surface of the composite frame, and the waterproofing capability of the composite frame is compromised.

### BRIEF DESCRIPTION OF THE DRAWINGS

Implementations of the present disclosure will now be described, by way of embodiments, with reference to the attached figures.

FIG. 1 is a diagrammatic view of an embodiment of a frame.

FIG. 2 is a diagrammatic view of an embodiment of metal plate.

FIG. 3 is an exploded, diagrammatic view of the frame of FIG. 1.

FIG. 4 is a partial cross-sectional view of the frame taken along IV-IV line of FIG. 1.

FIG. 5 is a flowchart of an exemplary embodiment of a method for manufacturing a frame.

FIG. 6 is a diagrammatic view of an embodiment of an electronic device.

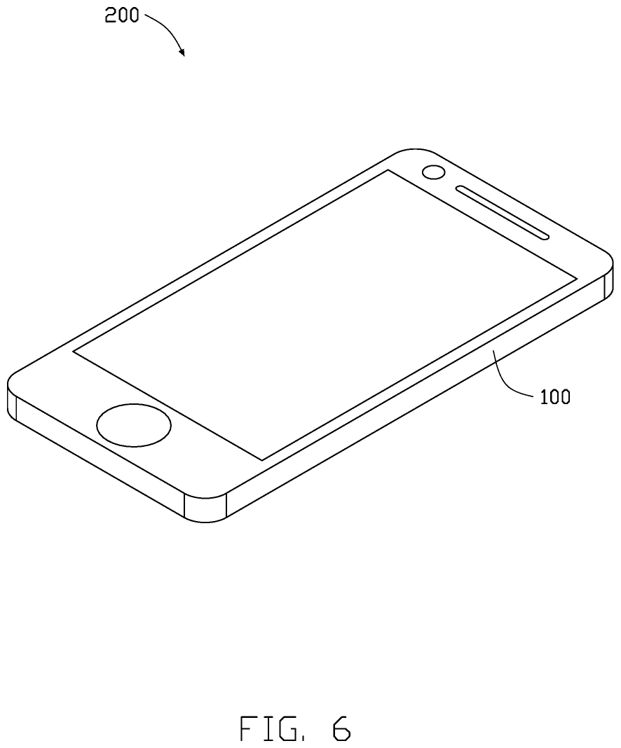

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts may be exaggerated to better illustrate details and features of the present disclosure.

The disclosure is illustrated by way of example and not by way of limitation in the figures of the accompanying drawings, in which like references indicate similar elements. It should be noted that references to “an” or “one” embodiment in this disclosure are not necessarily to the same embodiment, and such references mean “at least one.”

The term “comprising,” when utilized, means “including, but not necessarily limited to”; it specifically indicates open-ended inclusion or membership in the so-described combination, group, series, and the like.

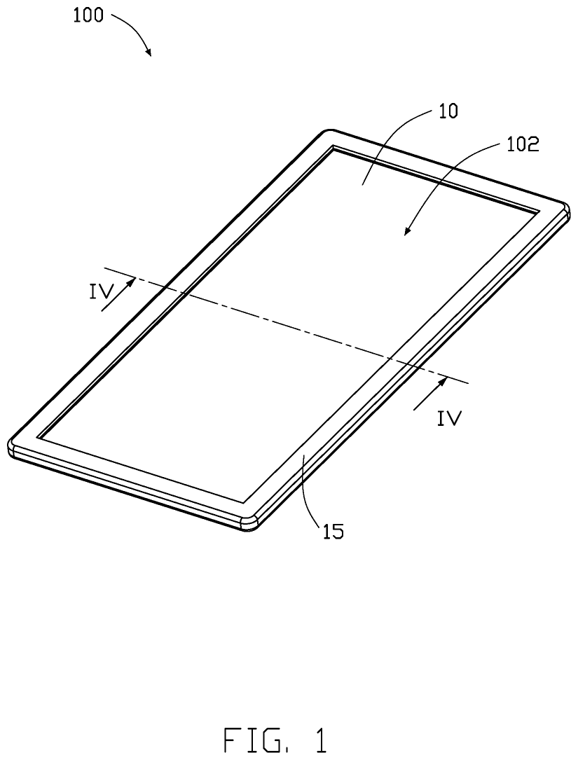

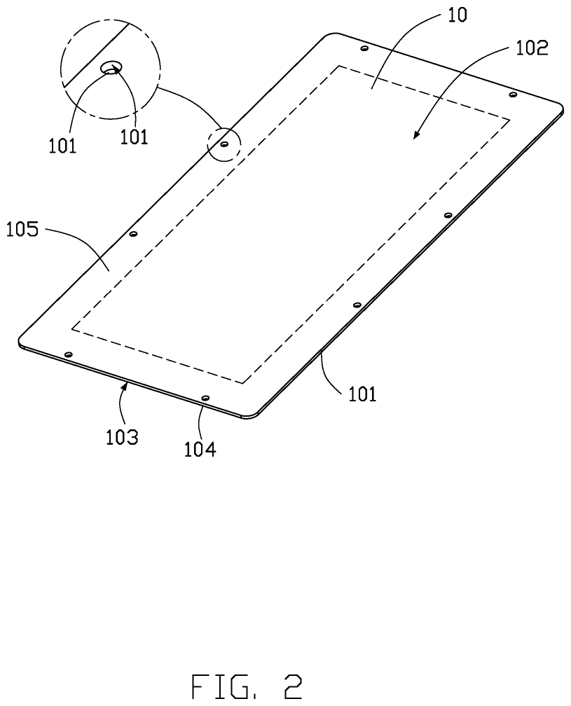

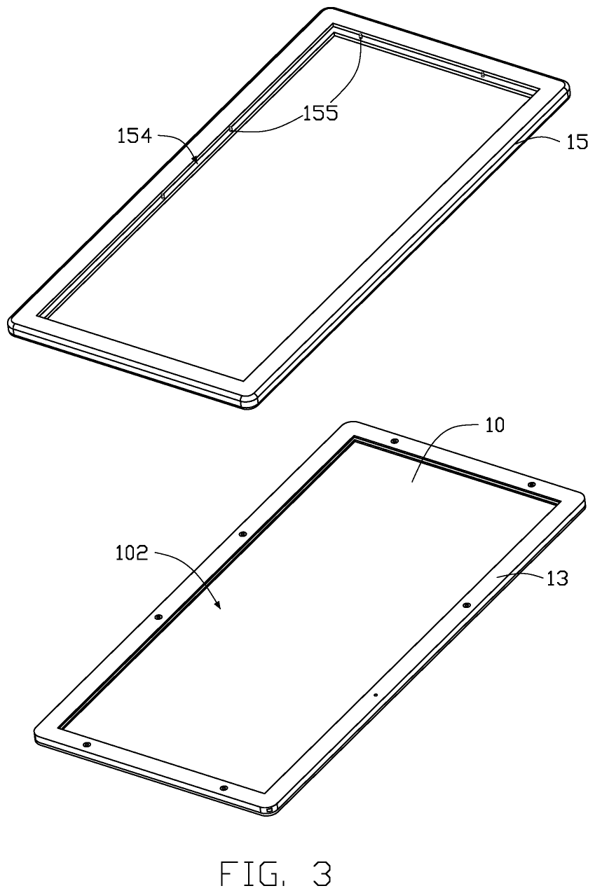

FIG. 1 illustrates an embodiment of a frame 100. The frame 100 comprises a metal plate 10, an adhesive film 13 (shown in FIG. 3) and a plastic border 15. The plastic border 15 is wrapped around a periphery 105 (shown in FIG. 2) of the metal plate 10. The adhesive film 13 is sandwiched between the plastic border 15 and the metal plate 10.

The adhesive film 13 increases a bonding strength between the plastic border 15 and the metal plate 10, thereby improving a waterproof capability of the frame 100.

Referring to FIG. 2, in at least one embodiment, the metal plate 10 is substantially rectangular and comprises an upper surface 102, a lower surface 103 facing away from the upper surface 102, and a side wall 104 connected between the upper surface 102 and the lower surface 103.

The periphery 105 comprises the side wall 104, a portion of the upper surface 102 adjacent the side wall 104, and a portion of the lower surface 103 adjacent the side wall 104.

In at least one embodiment, at least one grasping structure 101 may be formed on the periphery 105, and cooperates with the plastic border 15 to further improve the bonding strength between the plastic border 15 and the metal plate 10. In at least one embodiment, the grasping structure 101 is a grasping hole penetrating through the upper surface 102 of the metal plate 10 and the lower surface 103 of the metal plate 10. In another embodiment, the grasping structure 101 may be formed on the side wall 104.

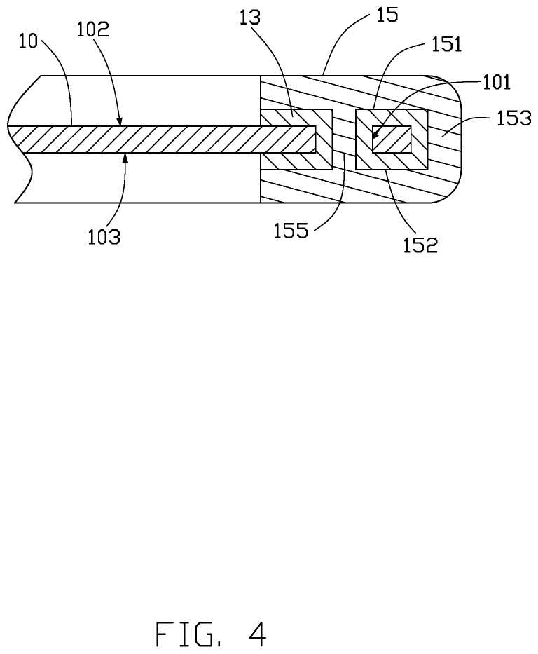

Referring FIG. 4, the adhesive film 13 covers the periphery 105 comprising an inner surface of the grasping structure 101, thereby improving a bonding force between the adhesive film 13 and the metal plate 10. In at least one embodiment, the adhesive film 13 has a thickness of 0.01 mm to 0.05 mm.

The adhesive film 13 may be made of a material comprising at least one of acrylic resin, polyurethane, and epoxy resin.

The plastic border 15 may further comprise at least one fixing portion 155. The fixing portion 155 protrudes from a surface of the plastic border 15 facing the metal plate 10, and is embedded in one grasping structure 101, thereby improving the bonding strength between the plastic border 15 and the metal plate 10. In an embodiment, the surface of the plastic border 15 facing the metal plate 10 comprises a first surface 151 facing the upper surface 102 and a second surface 152 facing the lower surface 103. The fixing portion 155 is connected between the first surface 151 and the second surface 152.

In at least one embodiment, the number of the grasping structure 101 and the number of the fixing portion 155 are more than one, respectively. The grasping structures 101 space from each other, and the fixing portions 155 space from each other.

In another embodiment, the grasping structure 101 may protrudes from a surface of the periphery 105, and the fixing portion 155 may be a fixing hole defined in the surface of the plastic border 15 facing the metal plate 10. The adhesive film 13 covers the periphery 105 comprising an outer surface of the grasping structure 101. In at least one embodiment, the grasping hole or the fixing hole may be a blind hole.

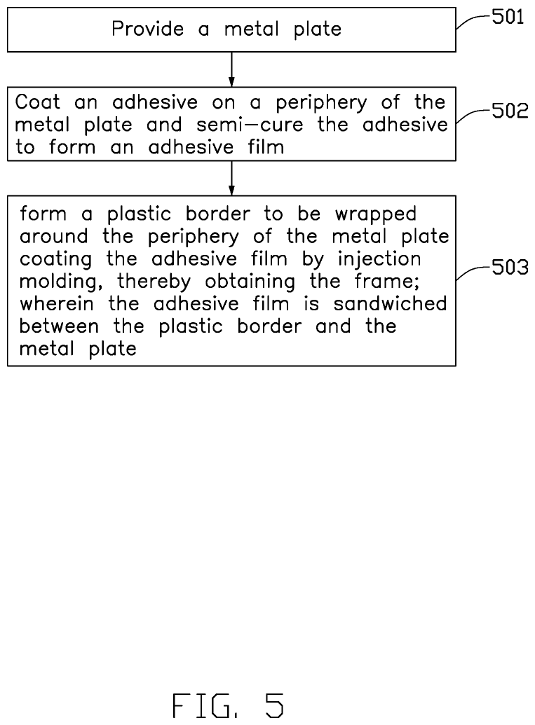

FIG. 5 illustrates a flowchart of a method for manufacturing a frame 100 (shown in FIG. 1) in accordance with an embodiment. The method is provided by way of embodiments, as there are a variety of ways to carry out the method. Each block shown in FIG. 5 represents one or more processes, methods, or subroutines, carried out in the exemplary method. Furthermore, the illustrated order of blocks is by example only and the order of the blocks can change. Additional blocks may be added or fewer blocks may be utilized, without departing from this disclosure. The method can begin at block 501.

At block 501, a metal plate 10 (shown in FIG. 2) is provided.

In at least one embodiment, referring to FIG. 2, the metal plate 10 is substantially rectangular and comprises an upper surface 102, a lower surface 103 facing away from the upper surface 102, and a side wall 104 connected between the upper surface 102 and the lower surface 103.

A periphery 105 of the metal plate 10 comprises the side wall 104, a portion of the upper surface 102 adjacent the side wall 104, and a portion of the lower surface 103 adjacent the side wall 104.

In at least one embodiment, at least one grasping structure 101 may be formed on the periphery 105. The grasping structure 101 may be a grasping hole penetrating through the upper surface 102 of the metal plate 10 and the lower surface 103 of the metal plate 10. In another embodiment, the grasping structure 101 may be formed on the side wall 104. In another embodiment, the grasping structure 101 may protrudes from a surface of the periphery 105.

At block 502, an adhesive is coated on the periphery 105 of the metal plate 10 and semi-cured to form an adhesive film 13 (shown in FIG. 3).

In at least one embodiment, the adhesive also is coated on an inner surface of the grasping structure 101 or an outer surface of the grasping structure 101.

At block 503, a plastic border 15 (shown in FIG. 1) is formed by injection molding. The plastic border 15 wraps around the periphery 105 of the metal plate 10 and coats the adhesive film 13, thereby obtaining the frame 100. The adhesive film 13 is sandwiched between the plastic border 15 and the metal plate 10.

In at least one embodiment, the plastic border 15 may further comprise at least one fixing portion 155 (shown in FIG. 3) correspondingly positioned in relation to the grasping structure 101.

In at least one embodiment, the fixing portion 155 protrudes from a surface of the plastic border 15 facing the metal plate 10, and is embedded in one grasping structure 101. In an embodiment, referring to FIG. 4, the surface of the plastic border 15 facing the metal plate 10 comprises a first surface 151 facing the upper surface 102 and a second surface 152 facing the lower surface 103. The fixing portion 155 is connected between the first surface 151 and the second surface 152.

In another embodiment, the fixing portion 155 may be a fixing hole defined in the surface of the plastic border 15 facing the metal plate 10.

The metal plate 10 is manufactured by the follow step:

providing a metal injection mold;

injecting metal powders into the metal injection mold, degreasing and sintering to obtain a metal base; and

subjecting the metal base to deburring and burring to obtain the metal plate 10.

In at least one embedment, at least one grasping element is formed on the metal injection mold, and the grasping structure is formed corresponding to the grasping element.

The adhesive film 13 is formed by the following step:

spraying, immersing or brushing the adhesive on the periphery 105 of the metal plate 10; and

semi-curing the adhesive at a temperature of 50 degree Celsius to 150 degree Celsius for 30 minutes to 100 minutes to form the adhesive film 13.

In at least one embodiment, the adhesive film 13 has a thickness of 0.01 mm to 0.05 mm.

In at least one embodiment, the adhesive comprises a resin component, a curing agent and a diluter. A mass ration of the resin component, the curing agent and the diluter is in a range of 10:1:1 to 10:1:10.

The resin component may comprise at least one of acrylic resin, polyurethane, and epoxy resin. The curing agent may be selected from a group consisting of isocyanate, amines, organic anhydrides, fatty acid compounds and any combination thereof. The diluter may be selected from a group consisting of ethyl acetate, ketone, ethyl alcohol, ethylene glycol, and any combination thereof.

The plastic border 15 is formed by the following step:

putting the metal plate 10 coated with the adhesive film 13 into an injection mold;

filling a molten plastic having a melting temperature of 220 degree Celsius to 380 degree Celsius into the injection mold having a temperature of 60 degree Celsius to 150 degree Celsius and at an injection pressure of 1000 kg/cm² to 2500 kg/cm², the molten plastic wrapping around the periphery 105 and coating the adhesive film 13, and maintaining the injection pressure at 1000 kg/cm² to 2500 kg/cm² for 5 seconds to 30 seconds; and

cooling to form the plastic border 15 and demoulding to obtain the frame 100.

The molten plastic activates the adhesive film 13 so that the plastic is bonded with the adhesive film 13 at a high strength, thereby achieving a firm boding of the metal plate 10 and the plastic through the adhesive film 13.

In at least one embodiment, the plastic comprises at least one of polycarbonate, polyamide, polybutylene terephthalate, polyphenylene sulfide, and polyether-ether-ketone.

In another embodiment, the plastic border 15 may be painted.

When the adhesive is coated the metal plate 10 to form the adhesive film 13, the adhesive fully infiltrates a surface of the periphery 105 of the metal plate 10 to achieve a seamless coverage at a molecular level between the adhesive film 13 and the metal plate 10. When the plastic border 15 is formed by the molten plastic, the molten plastic fully infiltrates the adhesive film 13 to achieve a seamless coverage at a molecular level between the plastic border 15 and the adhesive film 13. So that a seamless bonding between the plastic border 15 and the metal plate 10 is achieved, and the frame 100 has an excellent waterproof effect.

Depending on the embodiment, certain of the steps of methods described may be removed, others may be added, and the sequence of steps may be altered. It is also to be understood that the description and the claims drawn to a method may include some indication in reference to certain steps. However, the indication used is only to be viewed for identification purposes and not as a suggestion as to an order for the steps.

The frame 100 may be applied in electronic devices 200, mechanical device (not shown) or automobile (not shown). The electronic devices 200 may be mobile phones, pads, computers or cameras.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

What is claimed is:

1. A frame comprising:
a metal plate;
an adhesive film; and
a plastic border;
wherein the plastic border is wrapped around a periphery of the metal plate, the adhesive film is sandwiched between the plastic border and the metal plate.

2. The frame of claim 1, wherein the metal plate comprises an upper surface, a lower surface facing away from the upper surface, and a side wall connected between the upper surface and the lower surface; the periphery comprises the side wall, a portion of the upper surface adjacent the side wall, and a portion of the lower surface adjacent the side wall.

3. The frame of claim 2, wherein at least one grasping structure is formed on the periphery.

4. The frame of claim 3, wherein at least one fixing portion correspondingly positioned relative to the at least one grasping structure is formed on a surface of the plastic border facing the metal plate.

5. The frame of claim 4, wherein the at least one grasping structure is a grasping hole, each of the at least one fixing portion protrudes from the surface of the plastic border facing the metal plate, and is embedded in a corresponding one of the at least one grasping structure.

6. The frame of claim 5, wherein an inner surface of the at least one grasping structure is covered by the adhesive film.

7. The frame of claim 1, wherein a thickness of the adhesive film is between 0.01 mm and 0.05 mm.

8. A method for manufacturing a frame comprising:
providing a metal plate;
coating an adhesive on a periphery of the metal plate and semi-curing the adhesive to form an adhesive film; and
forming a plastic border wrapping around the periphery of the metal plate and coating the adhesive film by injection molding, thereby obtaining the frame;
wherein the adhesive film is sandwiched between the plastic border and the metal plate.

9. The method for manufacturing the frame of claim 8, wherein the adhesive is semi-cured at a temperature of 50 degree Celsius to 150 degree Celsius for 30 minutes to 100 minutes to form the adhesive film.

10. The method for manufacturing the frame of claim 8, wherein the adhesive comprises a resin component, a curing agent and a diluter, and a mass ratio of the resin component, the curing agent and the diluter is in a range of 10:1:1 to 10:1:10.

11. The method for manufacturing the frame of claim 10, wherein the resin component comprises at least one of acrylic resin, polyurethane, and epoxy resin; the curing agent is selected from a group consisting of isocyanate, amines, organic anhydrides, fatty acid compounds and any combination thereof; the diluter is selected from a group consisting of ethyl acetate, ketone, ethyl alcohol, ethylene glycol, and any combination thereof.

12. The method for manufacturing the frame of claim 8, wherein a thickness of the adhesive film is in a range of 0.01 mm to 0.05 mm.

13. The method for manufacturing the frame of claim 8, wherein the metal plate comprises an upper surface, a lower surface facing away from the upper surface, and a side wall connected between the upper surface and the lower surface; the periphery comprises the side wall, a portion of the upper surface adjacent the side wall, and a portion of the lower surface adjacent the side wall.

14. The method for manufacturing the frame of claim 13, wherein at least one grasping structure is formed on the periphery and covered by the adhesive film, at least one fixing portion correspondingly positioned relative to the at least one grasping structure is formed on a surface of the plastic border facing the metal plate.

15. A electronic device comprising:
a frame comprising:
a metal plate;
an adhesive film; and
a plastic border;
wherein the plastic border is wrapped around a periphery of the metal plate, the adhesive film is sandwiched between the plastic border and the metal plate.

16. The electronic device of claim 15, wherein the metal plate comprises an upper surface, a lower surface facing away from the upper surface, and a side wall connected between the upper surface and the lower surface; the periphery comprises the side wall, a portion of the upper surface adjacent the side wall, and a portion of the lower surface adjacent the side wall.

17. The electronic device of claim 16, wherein at least one grasping structure is formed on the periphery, at least one fixing portion correspondingly positioned relative to the at least one grasping structure is formed on a surface of the plastic border facing the metal plate.

18. The electronic device of claim 17, wherein the at least one grasping structure is a grasping hole, each of the at least one fixing portion protrudes from the surface of the plastic border facing the metal plate, and is embedded in one of the at least one grasping structure.

19. The electronic device of claim 18, wherein an inner surface of the at least one grasping structure is covered by the adhesive film.

20. The electronic device of claim 15, wherein a thickness of the adhesive film is in a range of 0.01 mm to 0.05 mm.
